(19) United States
(12) Patent Application Publication
(10) Pub. No.: US 2025/0218766 A1
(43) Pub. Date: Jul. 3, 2025

(54) STRUCTURES COMPRISING DIPOLE-LINED CONDUCTIVE WIRES AND RELATED SYSTEMS AND METHODS

(71) Applicant: ASM IP Holding B.V., Almere (NL)

(72) Inventors: Giuseppe Alessio Verni, Ismaning (DE); Andrea Illiberi, Leuven (BE); Michael Eugene Givens, Oud-Heverlee (BE)

(21) Appl. No.: 19/007,753

(22) Filed: Jan. 2, 2025

Related U.S. Application Data
(60) Provisional application No. 63/617,214, filed on Jan. 3, 2024.

(51) Int. Cl. H01L 21/02; H01L 21/768

(52) U.S. Cl. CPC H01L 21/02192; H01L 21/02183; H01L 21/0228; H01L 21/76834

(57) ABSTRACT

Methods and related structures and systems for inhibiting electromigration in back-end-of-line metal lines in integrated circuits. Embodiments of the presently disclosed structures comprise a dipole liner comprising a dipole that is positioned between a conductive wire and a low-k dielectric.

### CROSS-REFERENCE TO RELATED APPLICATION(S)

This Application claims the benefit of U.S. Provisional Application 63/617,214 filed on Jan. 3, 2024, the entire contents of which are incorporated herein by reference.

### FIELD OF INVENTION

The subject matter of the present disclosure is in the field of integrated circuit manufacturing, in particular in the fields of mid-end-of-line and back-end-of-line processing in integrated circuit manufacture.

### BACKGROUND OF THE DISCLOSURE

Current back-end-of-line (BEOL) metal vias and lines suffer from electromigration over time where electrons will escape through the low-k dielectric (LK) and cause dielectric breakdown on the device. Barrier metals can be employed between the LK and the copper (Cu) in order to reduce/slowdown the electromigration effect and improve the lifetime of the devices.

Tantalum nitride (TaN) liners are used to both improve Cu adhesion on the LK as well as reduce electromigration and Cu migration effects. The main limitation with those has to do with thickness and, consequently, resistivity impact on the Cu line. As via size is reduced, there will be in proportionally less and less space for the Cu for same liner size as the TaN has to have a minimum thickness of 1-2 nm in order to retain low enough resistivity and good enough barrier properties.

A partial solution to this problem is the use of 2D materials as barriers but they pose other challenges such as adhesion (due to inert behavior of 2D materials), good quality growth of the 2D materials across full wafer as well as need for selective growth of the 2D layers inside the vias.

Therefore, there remains a need for improved barriers for metal lines and vias.

### SUMMARY OF THE DISCLOSURE

Described herein is a structure comprising a conductive wire embedded in a low-k dielectric, wherein the conductive wire is surrounded by, and separated from, the low-k dielectric by means of a dipole liner, the dipole liner comprising a dipole.

In some embodiments, the structure further comprises a semiconductor wafer, wherein the conductive wire comprises a planar portion and a transverse portion, the planar portion being substantially parallel to the semiconductor wafer, and the transverse portion being substantially perpendicular to the semiconductor wafer.

In some embodiments, the dipole has a dipole moment that is directed from the conductive wire to the low-k dielectric.

In some embodiments, the dipole liner comprises a rare earth element.

In some embodiments, the rare earth element comprises at least one of lanthanum, scandium, and yttrium.

In some embodiments, the dipole liner comprises a rare earth element oxide.

In some embodiments, the rare earth element oxide is selected from La₂O₃, Sc₂O₃, and Y₂O₃.

In some embodiments, the dipole liner comprises metal oxynitride.

In some embodiments, the dipole liner comprises a post transition metal oxynitride.

In some embodiments, the post transition metal oxynitride comprises gallium oxynitride.

In some embodiments, the dipole liner has a uniform thickness.

In some embodiments, the structure further comprises a conductive liner, wherein the conductive liner is located between the conductive wire and the dipole liner.

In some embodiments, the conductive liner comprises a transition metal nitride.

In some embodiments, the transition metal nitride comprises tantalum nitride.

In some embodiments, the conductive liner comprises a 2D material.

In some embodiments, the 2D material comprises a transition metal dichalcogenide.

Further described herein is a structure comprising a dipole liner that comprises a dipole, the dipole liner separating a conductive wire from a low-k dielectric.

Further described herein is a method of forming a structure, the method comprising a step of providing a substrate to a reaction chamber, the substrate comprising a low-k dielectric, the method further comprising a step of forming a dipole liner comprising a dipole on the low-k dielectric.

In some embodiments, the dipole liner is formed by means of atomic layer deposition.

In some embodiments, the structure is a structure as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1, 2, and 3 show embodiments of structures according to an embodiment of the present disclosure.

FIGS. 4 and 5 show embodiments of methods according to the present disclosure.

FIG. 6 shows an embodiment of a system according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Indeed, purges can separate subsequent pulses by intermittently exposing the substrate to a purge gas. In some embodiments, each pulse is followed by a purge with a purge gas. Suitable purge gasses include inert or substantially inert gasses. In some embodiments, the purge gas comprises one or more of N₂ and a noble gas. Suitable noble gasses include He, Ne, Ar, Kr, and Xe.

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes may, but are not necessarily, comprised of a sequence of self-limiting surface reactions.

Described herein is an embodiment of a structure. The structure comprises a conductive wire embedded in a low-k dielectric. The conductive wire is surrounded by, and separated from, the low-k dielectric by means of a dipole liner. The dipole liner comprises a dipole.

A low-k dielectric can comprise silicon, oxygen, carbon, and hydrogen. A low-k dielectric can be porous. Optionally, a low-k dielectric can further comprise one or more other compounds such as nitrogen and boron.

Additionally, or alternatively, a structure according to an embodiment of the present disclosure can be described as a structure that comprises a dipole liner that in turn comprises a dipole. The dipole liner separates a conductive wire from a low-k dielectric.

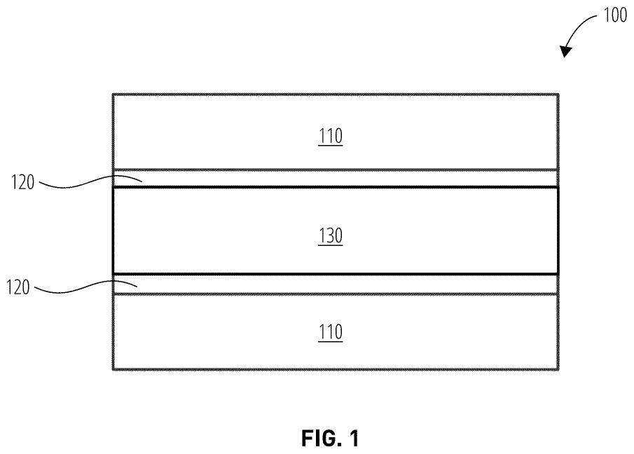

An embodiment of a structure is further explained in FIG. 1. In particular, and referring to FIG. 1, described is a structure 100 according to an embodiment of the present disclosure. The structure 100 comprises a conductive wire 130 that is embedded in a low-k dielectric 110. Exemplary conductive wires include conductive wires comprising a metal. Exemplary metals include copper, aluminum, silver, gold, ruthenium, molybdenum, and tungsten. The metal wire 130 is lined, i.e., surrounded, by of a dipole liner 120 as described herein. In other words, the dipole liner 120 separates the conductive wire 130 from the low-k dielectric 110. The dipole liner 120 comprises a dipole. Advantageously, such a dipole liner can inhibit electromigration in the conductive wire.

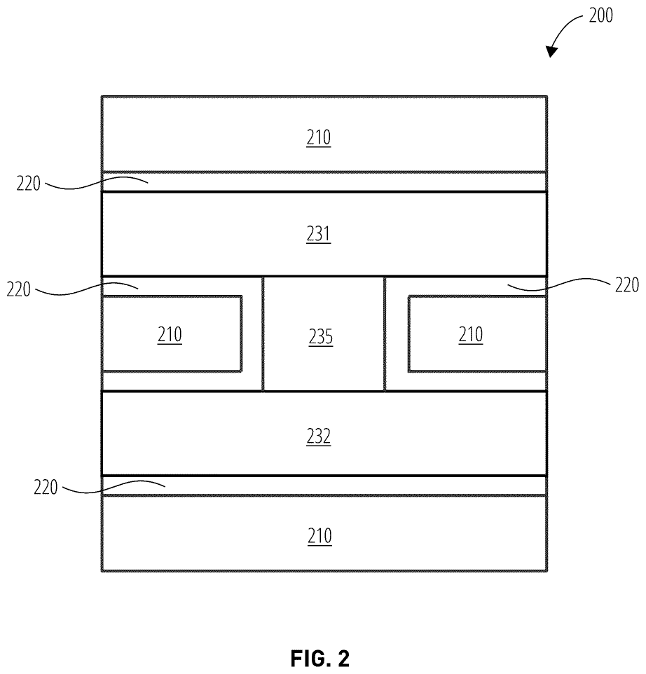

In some embodiments, the structure further comprises a semiconductor wafer. In such embodiments, the conductive wire can comprise a planar portion and a transverse portion. The planar portion can be substantially parallel to the semiconductor wafer. The transverse portion can be substantially perpendicular to the semiconductor wafer. Such an embodiment of a structure 200 is further explained in FIG. 2. This embodiment of a structure 200 comprises a first conductive wire 231 and a second conductive wire 232. The first conductive wire 231 and the second conductive wire 232 are electrically connected by means of a via 235. In some embodiments, the via 235, the first conductive wire 231, and the second conductive wire 232 can comprise the same material, for example the same metal. The via 235, the first conductive wire 231, and the second conductive wire 232 are embedded in a low-k dielectric 210. The via 235, the first conductive wire 231, and the second conductive wire 232 are lined, i.e., surrounded, by a dipole liner 220 which comprises a dipole. Advantageously, such a dipole liner can inhibit electromigration in at least one of the first conductive wire 231, the second conductive wire 232, and the via 235.

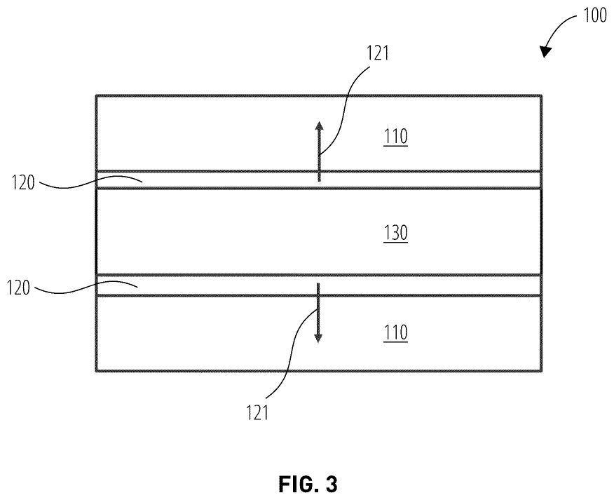

Advantageously, the dipole can have a dipole moment 121 that is directed from the conductive wire 130 to the low-k dielectric 110, as illustrated by FIG. 3. Thus, the dipole can comprise a negative share sheath around the metal wire that is surrounded by a positive charge sheath. Such a dipole can advantageously lead to electron repulsion from the interface between the low-k dielectric and the conductive wire. When electrical conduction in the conductive wire is mediated by electrons, as is the case for metal wires, the electrons are repelled from the edge of the conductive wire. Thus, electrons have less chance of colliding with defects at the edge of the conductive wire and consequently, electromigration can be advantageously reduced or even stopped completely.

In some embodiments, the conductive wire can comprise a metal such as copper, aluminum, molybdenum, tungsten, or silver. In some embodiments, the conductive wire comprises a transition metal. In some embodiments, the conductive wire comprises a noble metal. In some embodiments, the conductive wire comprises a post transition metal. In some embodiments, the conductive wire comprises an alkaline earth metal. In some embodiments, the conductive wire comprises an alkaline metal. In some embodiments, the conductive wire comprises a rare earth metal.

In some embodiments, the dipole liner comprises a rare earth element.

In some embodiments, the rare earth element comprises at least one of lanthanum, scandium, and yttrium.

In some embodiments, the dipole liner comprises a rare earth element oxide. In some embodiments, the dipole liner comprises one or more of a nitride, carbide, sulfide, selenide, telluride, boride, phosphide, and halide. In some embodiments, the dipole liner comprises one or more of a rare earth nitride, carbide, sulfide, selenide, telluride, boride, phosphide, and halide

In some embodiments, the rare earth element oxide is selected from La₂O₃, Sc₂O₃, and Y₂O₃.

In some embodiments, the dipole comprises a metal oxynitride. In some embodiments, the dipole comprises an alkaline earth metal oxynitride. In some embodiments, the dipole comprises an alkaline metal oxynitride. In some embodiments, the dipole comprises a transition metal oxynitride. In some embodiments, the dipole comprises a rare earth metal oxynitride.

In some embodiments, the dipole comprises a post transition metal oxynitride. Such dipoles can offer good resistance against electromigration and good adhesion between the low-k dielectric.

In some embodiments, the post transition metal oxynitride comprises gallium oxynitride.

In some embodiments, the dipole liner has a uniform thickness. A uniform thickness can be advantageously obtained using a cyclical deposition process such as atomic layer deposition (ALD). For example, the dipole liner can have a uniform thickness with a variation of at most 5 nm, or at most 4 nm, or at most 3 nm, or at most 2 nm, or at most 1 nm, or at most 0.5 nm, or at most 0.3 nm, or at most 0.1 nm.

In some embodiments, the structure further comprises a conductive liner. The conductive liner can be located between the conductive wire and the dipole liner. The conductive liner can be made from a different material than the conductive wire.

In some embodiments, the conductive liner has a uniform thickness. A uniform thickness can be advantageously obtained using a cyclical deposition process such as atomic layer deposition (ALD). For example, the conductive liner can have a uniform thickness with a variation of at most 5 nm, or at most 4 nm, or at most 3 nm, or at most 2 nm, or at most 1 nm, or at most 0.5 nm, or at most 0.3 nm, or at most 0.1 nm.

In some embodiments, the conductive liner comprises a transition metal nitride. In some embodiments, the conductive liner comprises an alkaline metal. In some embodiments, the conductive liner comprises an alkaline earth metal. In some embodiments, the conductive liner comprises a post transition metal. In some embodiments, the conductive liner comprises an oxide. In some embodiments, the conductive liner comprises a sulfide. In some embodiments, the conductive liner comprises a selenide. In some embodiments, the conductive liner comprises a telluride. In some embodiments, the conductive liner comprises a boride. In some embodiments, the conductive liner comprises a phosphide.

In some embodiments, the transition metal nitride comprises tantalum nitride.

In some embodiments, the conductive liner comprises a 2D material. In some embodiments, the 2D material comprises a transition metal dichalcogenide.

Further described herein is an embodiment of a method of forming a structure. The method comprises a step of providing a substrate to a reaction chamber. The substrate comprises a low-k dielectric. The method further comprises a step of forming a dipole liner on the low-k dielectric. The dipole liner comprises a dipole. The dipole liner can be formed by means of a cyclical deposition process such as atomic layer deposition. In some embodiments, forming a structure as described herein comprises executing a method as described herein.

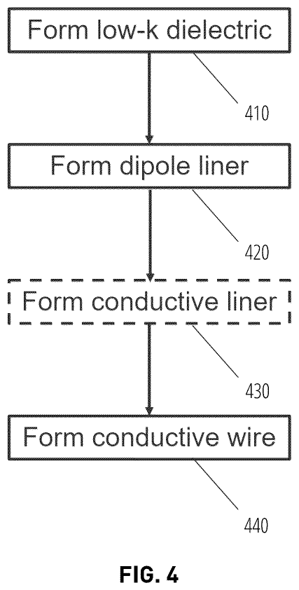

In some embodiments, a method according to an embodiment of the present disclosure comprises first forming a low-k dielectric. Such an embodiment is described with reference to FIG. 4. The embodiment of FIG. 4 particularly comprises forming a low-k dielectric 410. Then, a dipole liner is formed 420 on the low-k dielectric. Optionally, a conductive liner is formed 430 on the dipole liner. Then, a conductive wire is formed 440. The conductive wire can be formed on the conductive liner, if present, or directly on the dipole liner in case no conductive liner is present.

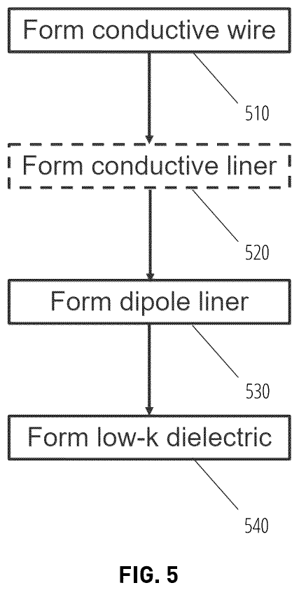

In some embodiments, a method according to an embodiment of the present disclosure comprises first forming a conductive wire. Such an embodiment is described with reference to FIG. 5. The embodiment of FIG. 5 particularly comprises forming a conductive wire 510. Optionally, a conductive liner is formed 520 on the conductive wire. Then, a dipole liner is formed 530. The dipole liner can be formed on the conductive liner, if present, or directly on the conductive wire in case no conductive liner is present. Then, a low-k dielectric is formed 540 on the dipole liner.

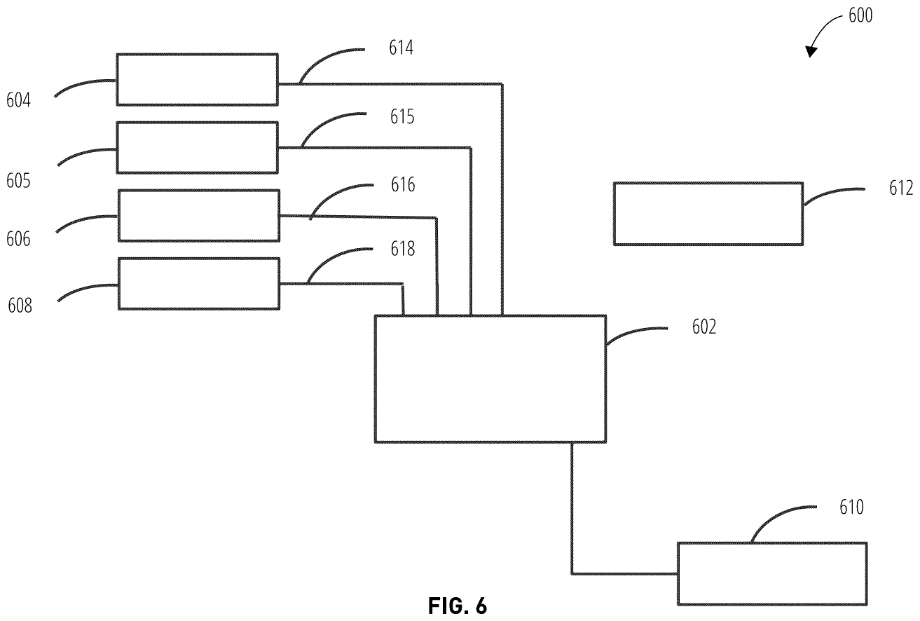

One or more of low-k materials, conductive wires, dipole liners, and conductive liners can be formed using a system 600 as described in FIG. 6. FIG. 6 illustrates a system 600 in accordance with exemplary embodiments of the disclosure. The system 600 can be used to perform a method as described herein and/or form a structure or device portion as described herein.

In the illustrated example, the system 600 includes one or more reaction chambers 602, a first precursor gas source 604, a reactant gas source 606, a purge gas source 608, an exhaust 610, and a controller 612.

The reaction chamber 602 can include any suitable reaction chamber, such as an ALD or CVD reaction chamber.

The first precursor gas source 604 can include a vessel and one or more precursors as described herein-alone or mixed with one or more carrier (e.g., noble) gases. The reactant gas source 606 can include a vessel and one or more reactants as described herein-alone or mixed with one or more carrier gases. The purge gas source 608 can include one or more noble gases as described herein. Although illustrated with four gas sources 604-608, the system 600 can include any suitable number of gas sources. The gas sources 604-608 can be coupled to reaction chamber 602 via lines 614-618, which can each include flow controllers, valves, heaters, and the like.

The exhaust 610 can include one or more vacuum pumps.

The controller 612 includes electronic circuitry and software to selectively operate valves, manifolds, heaters, pumps, and other components included in the system 600. Such circuitry and components operate to introduce precursors and purge gases from the respective sources 604-608. The controller 612 can control timing of gas pulse sequences, temperature of the substrate and/or reaction chamber, pressure within the reaction chamber, and various other operations to provide proper operation of the system 600. The controller 612 can include control software to electrically or pneumatically control valves to control flow of precursors, reactants, and purge gases into and out of the reaction chamber 602. The controller 612 can include modules such as a software or hardware component, e.g., a FPGA or ASIC, which performs certain tasks. A module can advantageously be configured to reside on the addressable storage medium of the control system and be configured to execute one or more processes.

Other configurations of the system 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 602. Further, as a schematic representation of a system, many components have been omitted for simplicity of illustration, and such components may include, for example, various valves, manifolds, purifiers, heaters, containers, vents, and/or bypasses.

During operation of the reactor system 600, substrates, such as semiconductor wafers (not illustrated), are transferred from, e.g., a substrate handling system to the reaction chamber 602. Once substrate(s) are transferred to the reaction chamber 602, one or more gases from the gas sources 604-608, such as precursors, reactants, carrier gases, and/or purge gases, are introduced into the reaction chamber 602.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub combinations of the various processes, systems, and configurations, and other features, functions, acts, and/or properties disclosed herein, as well as any and all equivalents thereof.

1. A structure comprising a conductive wire embedded in a low-k dielectric, wherein the conductive wire is surrounded by, and separated from, the low-k dielectric by a dipole liner, the dipole liner comprising a dipole.

2. The structure according to claim 1 further comprising a semiconductor wafer, wherein the conductive wire comprises a planar portion and a transverse portion, the planar portion being substantially parallel to the semiconductor wafer, and the transverse portion being substantially perpendicular to the semiconductor wafer.

3. The structure according to claim 1, wherein the dipole has a dipole moment that is directed from the conductive wire to the low-k dielectric.

4. The structure according to claim 1, wherein the dipole liner comprises a rare earth element.

5. The structure according to claim 4, wherein the rare earth element comprises at least one of lanthanum, scandium, and yttrium.

6. The structure according to claim 4, wherein the dipole liner comprises a rare earth element oxide.

7. The structure according to claim 6, wherein the rare earth element oxide is selected from La₂O₃, Sc₂O₃, and Y₂O₃.

8. The structure according to claim 4, wherein the dipole liner comprises a metal oxynitride.

9. The structure according to claim 8, wherein the dipole liner comprises a post transition metal oxynitride.

10. The structure according to claim 9, wherein the post transition metal oxynitride comprises gallium oxynitride.

11. The structure according to claim 1, wherein the dipole liner has a uniform thickness.

12. The structure according to claim 1 further comprising a conductive liner, wherein the conductive liner is located between the conductive wire and the dipole liner.

13. The structure according to claim 12, wherein the conductive liner comprises a transition metal nitride.

14. The structure according to claim 13, wherein the transition metal nitride comprises tantalum nitride.

15. The structure according to claim 14, wherein the conductive liner comprises a 2D material.

16. The structure according to claim 15, wherein the 2D material comprises a transition metal dichalcogenide.

17. A structure comprising a dipole liner that comprises a dipole, the dipole liner separating a conductive wire from a low-k dielectric.

18. A method of forming a structure, the method comprising a step of providing a substrate to a reaction chamber, the substrate comprising a low-k dielectric, the method further comprising a step of forming a dipole liner comprising a dipole on the low-k dielectric.

19. The method according to claim 18, wherein the dipole liner is formed by atomic layer deposition.

20. The method according to claim 18, wherein the structure comprises one of:
a conductive wire embedded in a low-k dielectric, wherein the conductive wire is surrounded by, and separated from, the low-k dielectric by a dipole liner, the dipole liner comprising a dipole; or
a dipole liner that comprises a dipole, the dipole liner separating a conductive wire from a low-k dielectric.
